(19) United States
(12) Patent Application Publication
(10) Pub. No.: US 2025/0380612 A1
(43) Pub. Date: Dec. 11, 2025

(54) METHOD FOR DEPOSITING HIGHLY DOPED ALUMINUM NITRIDE PIEZOELECTRIC MATERIAL

(71) Applicant: Lam Research Corporation, Fremont, CA (US)

(72) Inventors: Willem Cornelis Lambert HOPMAN, Deventer (NL); Jan Matthijn DEKKERS, Aadorp (NL); Jeroen Aaldert HEUVER, Enschede (NL)

(21) Appl. No.: 18/836,657

(22) PCT Filed: Jan. 27, 2023
(86) PCT No.: PCT/US2023/061478

§ 371 Date: Aug. 7, 2024

(30) Foreign Application Priority Data
Feb. 8, 2022 (EP) 22155617.8

(51) Int. Cl. H10N 30/076; C23C 14/06; H10N 30/853

(52) U.S. Cl. CPC H10N 30/076; C23C 14/0641; H10N 30/853

(57) ABSTRACT

The invention relates to a method for manufacturing a doped wurtzite aluminum nitride piezoelectric thin film material, which method comprises the steps of: providing a deposition device, such as a pulsed lased deposition device or a physical vapor deposition device, with a target and a substrate, wherein the target material is a doped aluminum nitride composite, wherein the doping element is a rare earth element, preferably scandium; depositing a first layer of the target material on the substrate by operating the deposition device, wherein the kinetic energy of the plasma particles being deposited is above a first threshold value; depositing a second layer of the target material on top of the first layer by operating the deposition device, wherein the kinetic energy of the plasma particles being deposited is below a second threshold value and wherein the first threshold value is larger than the second threshold value.

### FIELD

The invention relates to a method for manufacturing a doped wurtzite aluminum nitride piezoelectric thin film material, which method comprises the steps of: providing a deposition device, such as a pulsed lased deposition device or a physical vapor deposition device, with a target and a substrate, wherein the target material is a doped aluminum nitride composite, wherein the doping element is a rare earth element, preferably scandium; depositing a first layer of the target material on the substrate by operating the deposition device, wherein the kinetic energy of the plasma particles being deposited is above a first threshold value; and depositing a second layer of the target material on top of the first layer by operating the deposition device, wherein the kinetic energy of the plasma particles being deposited is below a second threshold value.

For the invention, the kinetic energy of the plasma particles is defined by the plasma temperature measured in electron volts (eV). The plasma temperature is a common measure of the thermal kinetic energy per particle.

### BACKGROUND

It is known from, for example EP 3340327 in the name of the Applicant, to manufacture a piezoelectric material with a pulsed laser deposition device. From this publica-tion it is also known to apply two or more layers of the target material onto a substrate, while using different process parameters for each of the layers.

EP 3340327 teaches to use a low deposition rate for the first layer and to use a high deposition rate for the second and further layers. This ensures that the second layer has a less erratic crystal structure compared to a piezoelectric material, which has been grown using only the high deposition rate.

When a doped aluminum nitride composite, in particular scandium aluminum nitride, is used to manufacture a piezoelectric material, it is known that by increasing the scandium concentration, the piezoelectric response also increases. (See: Morito Akiyama et. al. (2009) “Influence of growth temperature and scandium concentration on piezoelectric response of scandium aluminum nitride alloy thin films”. Applied Physics Letters 95, 162107 (2009)).

However, if the doping concentration is increased to high values (>20% scandium), unwanted features start to appear on the film surface. These features are visible with a scanning electron microscope (SEM) on the surface of the deposited layer as triangular zones, which are called inverted domains. The inverted domains are known to negatively influence the properties of the scandium aluminum nitride thin film. Hence it is important to suppress the amount of the inverted domains.

If the concentration of the doping element is further increased beyond a certain value (e.g. >43%), then a dramatic drop in the piezoelectric response is observed. This is caused by a phase transition to a non-polar rocksalt-type structure of the scandium aluminum nitride, which no longer has piezoelectric properties. Therefore it is desired to maintain the wurtzite phase at the highest doping concentration possible. The amount of inverted domains and concentration at which the dramatic drop in piezoelectric response is observed, is dependent on the interface between the substrate and the layer of target material (See: Simon Fitchner et. al. (2017) “Identifying and overcoming the interface originating c-axis instability in highly Sc enhanced AlN for piezoelectric micro-electromechanical systems” Journal of Applied Physics 122, 035301 (2017)).

In order to improve the interface between the substrate and the layer of target material it is known, using a physical vapor deposition, to apply a pre-cleaning treatment, such as etching, milling or passivation, onto the surface of the wafer or the electrode stack on which the scandium aluminum nitride thin film needs to be applied. Further, a first thin layer may be applied using another target material, typically undoped aluminum nitride or scandium doped aluminum nitride with a lower scandium concentration than the second bulk layer. This first layer acts as a template for the stabilization of the wurtzite phase of second bulk layer of the highly doped scandium aluminum nitride. These steps require additional (costly) equipment and slows down the thin film manufacturing process.

With these additional steps it is possible to use scandium as a doping element up to a concentration of about 30% in commercial production facilities and up to a concentration of about 43% in laboratory settings (See: Morito Akiyama et. al. (2009) “Influence of growth temperature and scandium concentration on piezoelectric response of scandium aluminum nitride alloy thin films”. Applied Physics Letters 95, 162107 (2009))

According to theoretical calculations, wurtzite scandium aluminum nitride is stable up to a concentration of 56% (See: M. A. Moram (2014) “ScGaN and ScAIN: emerging nitride materials”. Journals of Materials Chemistry A, 2014, 2, 6042-6050; Miguel A Caro et. al. (2015) “Piezoelectric coefficients and spontaneous polarization of ScAIN” Journal of Physics: Condensed Matter, 27 (2015) 245901). However, such high concentrations up to 56% appear at least currently not possible using a cleaning treatment and/or seeding layer with lower Sc doping.

### SUMMARY

As a result, it is an object of the invention to reduce the above mentioned disad-vantages, while be able to use a deposition device, such as a pulsed lased deposition device or a physical vapor deposition device, for manufacturing a piezoelectric thin film material out of a doped aluminum nitride composite.

This object is achieved according to the invention with the method according to the preamble, which is characterized in that the first threshold value is larger than the second threshold value. Consequently the stress in the first layer is typically lower than the stress in the second layer.

By depositing the first layer with the target material, wherein the kinetic energy of the plasma particles being deposited is above a first threshold value, i.e. a high level, the substrate is in practice cleaned and smoothed, such that the chance on formation of inverted domains as a result of the quality of the substrate is substantially reduced. When subsequently a second layer of target material is deposited, wherein the kinetic energy of the plasma particles being deposited is below a second threshold value, i.e. a low level, the second layer of target material can be grown under optimal conditions, while the chance on inverted domain formation is reduced and accordingly a higher concentration of the doping element can be used in the wurtzite aluminum nitride, then would be possible without the depositing of the first layer with the kinetic energy of the particles at a high level.

A further advantage of the method according to the invention is that only a single target material is used, which contributes to the quality of the manufactured piezoelectric thin film material and provides no delays in the process for exchanging target materials or the use of an additional reactor for the formation of the first layer. Also the use of a cleaning chamber that adds costs to the manufacturing equipment is prevented.

Further, the second layer of target material is applied directly onto the first layer of target material and there is no need to move the substrate to a cleaning position first, perform the cleaning treatment and then move the substrate with the cleaned substrate or electrode surface to a position in which the layer of another target material is applied. So, compared to the known physical vapor deposition method, in which three separate chambers (cleaning, first layer, and second layer using a different target material compared to the first layer) are used, the method of the invention can be used in a single chamber.

In a preferred embodiment of the method according to the invention the first layer of the target material is deposited onto the substrate without any interim treatment of the substrate. The substrate could be the wafer, any passivation layer, or could be an electrode layer.

With the invention only the process parameters are changed between the first layer and the second layer, and no physical displacement of the substrate and/or the target material is required to obtain a doped aluminum nitride thin film.

In a further preferred embodiment of the method according to the invention the first threshold value is more than 90 eV, preferably in the range of 100 eV-160 eV. This results in a stress of the first layer of less than-400 MPa (megapascals). Depositing a target material with plasma particles having such a high kinetic energy ensures for an optimal surface to grow a second layer of target material onto, which allows high concentrations of the doping element, which would otherwise not be possible as many inverted domains may form and/or a phase transition would occur, and the manufactured thin film material would have lost the piezoelectric properties.

In yet a further preferred embodiment of the method according to the invention the second threshold value is less than 90 eV, preferably in the range of 40 eV-80 eV. This results in a thin film stress of the second layer typically in the range from −400 MPa to +600 MPa. This relative low kinetic energy for the plasma particles ensures an optimal growth of the second layer of target material, which in the end will provide the desired piezoelectric properties to the thin film material.

Although, the kinetic energy with which the plasma particles arrive at the substrate is directly related to the effect achieved with the invention, in practice it proves difficult to accurately measure the kinetic energy of the plasma particles. Currently a probe is used to measure the kinetic energy of plasma particles. Such a probe needs to be positioned closely to the surface of the substrate. Furthermore, if the kinetic energy of plasma particles generated by a pulsed laser deposition device is to be measured, the very short pulses of the laser and as a consequence generated plasma, further increase the difficulty of reliably measuring the kinetic energy.

Therefore, it is a common method to derive the kinetic energy of the plasma particles from the stress generated in the layer deposited by said plasma particles. The stress can be accurately measured for example with a bow meter.

In line with the above, it is an alternative embodiment of the method according to the invention wherein the kinetic energy of the plasma particles is derived from the stress in the layer deposited by said plasma particles and wherein the kinetic energy of the plasma particles is above the first threshold value while depositing the first layer by keeping the stress in said first layer lower than-500 MPa, preferably lower than-1000 MPa.

In another alternative embodiment of the method according to the invention wherein the kinetic energy of the plasma particles is derived from the stress in the layer deposited by said plasma particles and wherein the kinetic energy of the plasma particles is below the second threshold value while depositing the second layer by keeping the stress in said first layer higher than-500 MPa, preferably in the range of −400 MPa to +600 MPa.

In a further embodiment of the method according to the invention the thickness of the first layer of the target material is in the range of 10 nm-50 nm (nanometers). The expo-sure of the wafer or electrode during the deposition of such a thickness of the film at high kinetic energy is sufficient to provide the necessary surface cleaning. Also, such a thickness is sufficient to provide a high quality interface with the second layer and allows for the high concentrations of the doping element, without the chance on phase transition.

In still a further embodiment of the method according to the invention the concentration of the doping element is at least 20% of the target material.

### BRIEF DESCRIPTION OF THE DRAWINGS

FIGS. 1A-1C show the steps of the method according to the invention.

FIG. 2A shows a SEM photograph of the surface of a piezoelectric thin film material using a conventional technique.

FIG. 2B shows a SEM photograph of the surface of a piezoelectric thin film material using the method according to the invention.

FIG. 3 shows a diagram of the piezoelectric response in relation to the concentration of a doping element.

### DETAILED DESCRIPTION

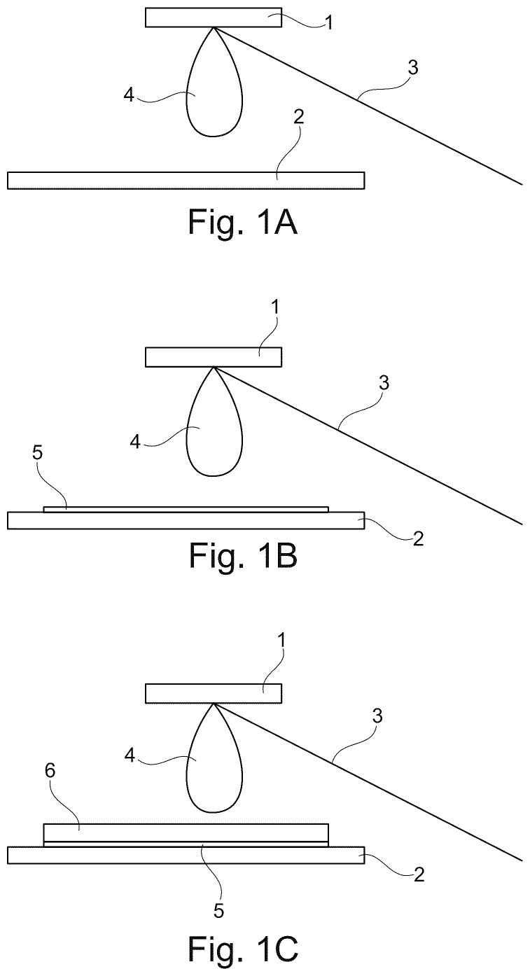

FIG. 1A shows schematically a pulsed laser deposition device with a target 1 and a substrate 2. A pulsed laser 3 is directed onto the target 1, such that a plasma plume 4 is generated. In order to deposit the target material over the whole surface of the substrate 2, the laser beam 3 is for example scanned over the target 1, while the substrate 2 is rotated, or the substrate 2 is moved linear in two dimensions such that the plasma plume 4 can cover the whole surface of the substrate 2.

According to the invention a first layer 5 of target material is deposited onto the substrate 2 using a high kinetic energy above a first threshold value. (See FIG. 1B).

After the first layer 5 of target material is deposited, the parameters of the pulsed laser deposition device are adjusted, such that a second layer 6 of target material is deposited onto the first layer 5 using a low kinetic energy below a second threshold value. (see FIG. 1C).

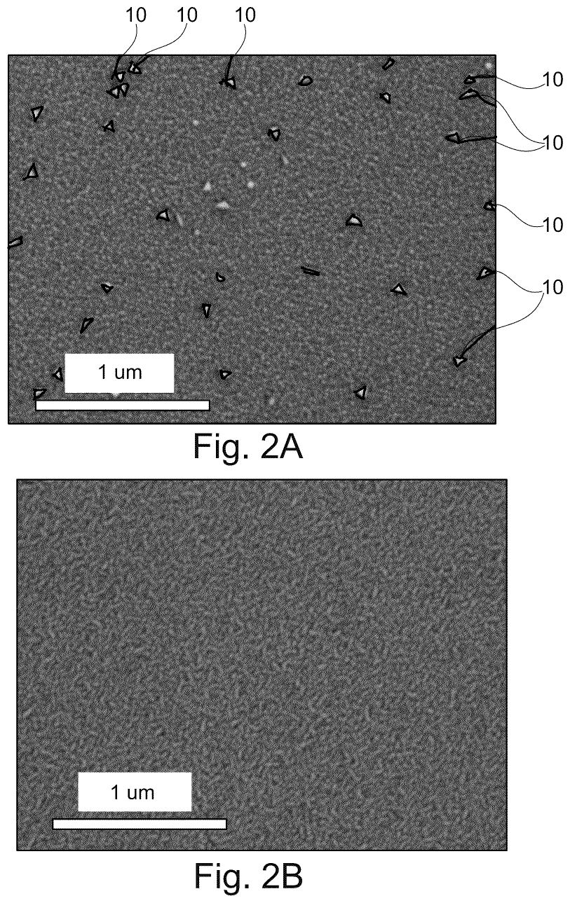

FIG. 2A shows a SEM photograph of the surface of a thin film material out of scandium aluminum nitride having a concentration of scandium of 40% and which has been deposited with a pulsed laser deposition device. During deposition of the target material, the kinetic energy of the plasma particles was kept at 60 eV. The resulting thin film stress is +300 MPa (tensile). It is clear from this photograph, that zones 10 are present, which are the so-called inverted domains. This causes the properties of the thin film, such as the piezoelectric response to drop, despite the high concentration of scandium.

FIG. 2B shows a SEM photograph of the surface of a thin film material manufactured with the method according to the invention. The concentration of scandium is equal, i.e. 40%, as with the thin film material of FIG. 2A. However, a first layer of target material was deposited onto the substrate, which was provided with an electrode layer, using a kinetic energy for the plasma particles at 150 eV. After about 10 nm-50 nm of this first layer was deposited, the parameters of the pulsed laser deposition device were changed, such that the kinetic energy of the plasma particles was lowered to 50 eV, close to the value used for the thin film material of FIG. 2A. The resulting stress of the combined thin first layer and thick second layer is +300 MPa (tensile), similar to the stress in the film of FIG. 2A.

FIG. 2B clearly shows, that with the method according to the invention, zones 10 are no longer present and that therefore the manufactured piezoelectric thin film material optimally benefits of the high concentration of scandium.

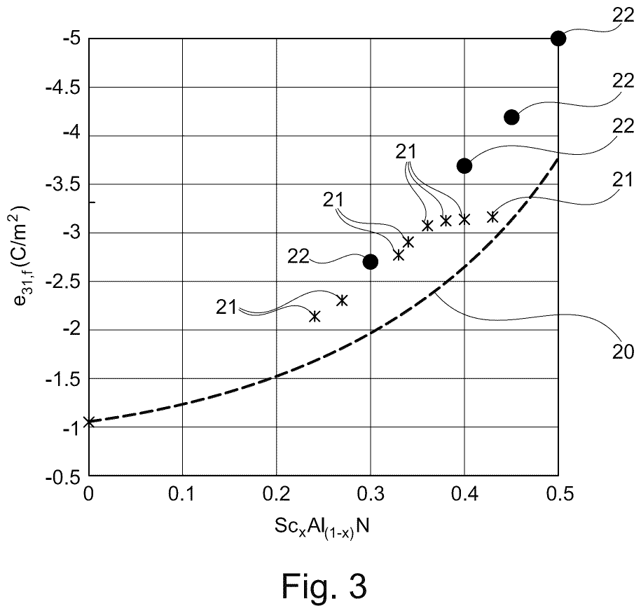

FIG. 3 shows a diagram with the piezoelectric response e31,f along the Y-axis and the concentration of scandium in aluminum nitride along the X-axis.

The curve 20 shows the theoretical piezoelectric response dependent on the concentration of scandium according to Miguel A Caro et. al. (2015).

The data points 21 show the results of the prior art method in which physical vapor deposition is used as suggested by Simon Fitchner et. al. (2017). It is clear that at about 35% of scandium, the data points 21 no longer follow the theoretical curve 20 and that the piezoelectric response is affected as a result of inverted domains as shown in FIG. 2A, or the start of formation of rocksalt phase in the thin film.

The data points 22 show the results of the method according to the invention. For these data points 22, a first layer of scandium aluminum nitride target material was deposited using a plasma particle kinetic energy of 150 eV. Then a second layer of scandium aluminum nitride target material was deposited using a plasma kinetic energy of 50 eV. It is clear from the data points 22 that even up to 50% of scandium in the wurtzite aluminum nitride, the piezoelectric response was still not heavily affected by phase transition or inverted domains and that the data points 22 still are higher than when using the known physical vapor deposition technique.

1. A method for manufacturing a doped wurtzite aluminum nitride piezoelectric thin film material, the method comprising:
providing a deposition device with a target and a substrate, wherein a target material of the target is a doped aluminum nitride composite, and wherein a doping element of the doped aluminum nitride composite is a rare earth element, preferably scandium;
depositing a first layer of the target material on the substrate by operating the deposition device, wherein a kinetic energy of plasma particles being deposited to form the first layer of the target material is above a first threshold value; and
depositing a second layer of the target material on top of the first layer by operating the deposition device, wherein a kinetic energy of plasma particles being deposited to form the second layer is below a second threshold value,
wherein the first threshold value is larger than the second threshold value.

2. The method according to claim 1, wherein the first layer of the target material is deposited onto the substrate without any interim treatment of the substrate.

3. The method according to claim 1, wherein the first threshold value is more than 90 eV.

4. The method according to claim 1, wherein the second threshold value is less than 90 eV, preferably in the range of 40 eV 80 eV.

5. The method according to claim 1, wherein the kinetic energy of the plasma particles being deposited to form the first layer is derived from a stress in the first layer.

6. The method according to claim 1, wherein the kinetic energy of the plasma particles deposited to form the second layer is derived from a stress in the second layer.

7. The method according to claim 1, wherein a thickness of the first layer is in a range of 10 nm-50 nm.

8. The method according to claim 1, wherein a concentration of the doping element is at least 20 molar % of a total amount of aluminum and the doping element in the target material.

9. The method according to claim 1, wherein the rare earth element is scandium.

10. The method according to claim 5, wherein the kinetic energy of the plasma particles deposited to form the first layer is maintained above the first threshold value while depositing the first layer by keeping the stress in the first layer lower than −1000 MPa.

11. The method according to claim 6, wherein the kinetic energy of the plasma particles deposited to form the second layer is maintained below the second threshold value while depositing the second layer by keeping a stress in the second layer in a range of −400 MPa to +600 MPa.

12. The method according to claim 1, wherein the deposition device is a pulsed laser deposition device or a physical vapor deposition device.

13. The method of claim 3, wherein the first threshold value is in the range of 100 eV-160 eV.

14. The method of claim 4, wherein the second threshold value is in the range of 40 eV-80 eV.

15. A deposition device comprising a pulsed laser, the deposition device being adapted to hold a substrate and a target for depositing a film on the substrate by directing laser energy from the pulsed laser at the target, the deposition device being configured to:
deposit a first layer of doped aluminum nitride on a substrate by directing the laser energy at a doped aluminum nitride target, such that a kinetic energy of plasma particles being deposited to form the first layer of doped aluminum nitride is above a first threshold value; and
deposit a second layer of doped aluminum nitride on top of the first layer of doped aluminum nitride such that a kinetic energy of plasma particles being deposited to form the second layer of doped aluminum nitride is below a second threshold value,
wherein the first threshold value is larger than the second threshold value.

16. The deposition device according to claim 15, wherein the first threshold value is more than 90 eV.

17. The deposition device according to claim 15, further comprising the doped aluminum nitride target, wherein the doped aluminum nitride target is doped with a rare earth element at a concentration of at least 20 molar % of a total concentration of aluminum and the doping element in the target material.

18. The deposition device according to claim 17, wherein the rare earth element is scandium.

19. The deposition device according to claim 15, wherein the deposition device is configured to keep a stress in the first layer lower than −500 MPa while depositing the first layer.

20. An article, comprising:
a substrate; and
a piezoelectric thin film on the substrate, the piezoelectric thin film comprising
a first layer of doped aluminum nitride on the substrate, the first layer of doped aluminum nitride having a first, lower stress, and
a second layer of doped aluminum nitride on the first layer of doped aluminum nitride, the second layer of doped aluminum nitride having a second, higher stress than the first layer of doped aluminum nitride.

21. The article of claim 20, wherein the first layer of doped aluminum nitride and the second layer of doped aluminum nitride are a same material.

22. The article of claim 21, wherein the first layer of doped aluminum nitride and the second layer of doped aluminum nitride are doped with scandium.

23. The article of claim 20, wherein the piezoelectric thin film is substantially free of inverted domains.

24. The article of claim 20, wherein the piezoelectric film has a general formula of ScₓAl₍₁₋ₓ₎N, and wherein x is between 0.35 and 0.5.

25. The article of claim 20, wherein the first layer of doped aluminum nitride has a thickness of 10 nm to 50 nm.

26. The article of claim 20, wherein the second layer of doped aluminum nitride is thicker than the first layer of doped aluminum nitride.
